(19) United States
(12) Patent Application Publication
(10) Pub. No.: US 2005/0029909 A1
(43) Pub. Date: Feb. 10, 2005

(54) Mounting structure of resin part on chassis, and method thereof

(76) Inventor: Kenji Kitatani, Osaka (JP)

Correspondence Address: Jonathan P. Osha;Osha & May L.L.P., Suite 2800, 1221 McKinney St., Houston, TX, 77010, US

(21) Appl. No.: 10/913,602

(22) Filed: Aug. 5, 2004

(30) Foreign Application Priority Data
Aug. 8, 2003 (JP) P. 2003-289523

(51) Int. Cl. H05K 7/02

(52) U.S. Cl. 312/223.2

(57) ABSTRACT

A mounting structure of a resin part on a chassis includes a leg portion of the resin part, and a mounting part in the chassis to mount the leg portion thereon by tightening the leg portion with a screw. Preferably, the mounting part includes an upper piece in a horizontal direction which is cut and erected upwardly and both side pieces of which are integral with the chassis and inclined downwardly in an outward direction, the leg portion includes a blind hole, the upper piece includes a screw hole vertically passing through, the resin part is mounted on the chassis by inserting the leg portion horizontally into an opening below the upper piece and screwing the screw into the screw hole, and a lower end of the screw comes into contact with a bottom of the blind hole and does not protrude to a back face side of the chassis.

### BACKGROUND OF THE INVENTION

1. Field of the Invention

The present invention relates to a mounting structure of a resin part on a chassis for mounting a leg portion of the resin part on a mounting part provided in the chassis by tightening the leg portion with a screw.

2. Description of the Related Art

Conventionally, in order to fix a resin part to amounting part of a chassis by a screw, as shown in FIG. 4A for example, a screw 103 has been inserted through a screw insertion hole 102 which is provided in a resin part 101, and this screw 103 has been screwed into a screw hole 106 which is provided in a raised part 105 formed in a chassis 104 thereby to tighten the resin part for securing.

However, being constructed in this manner, there has been a problem that the screw 103 may come out from the screw hole 106 in the chassis 104 to a back face side, as shown in FIG. 4B, and such a risk that a finger may be injured by a tip end of this screw 103 has arisen.

In order to solve this problem, it has been necessary to round the tip end of the screw, or to employ a screw of a particular type.

A first example of the prior art is shown in FIGS. 5, 6A, and 6B. In this example, on occasion of mounting an electric part 210 on a printed board 230, the electric part 210 is reinforced by securing it to a mechanical chassis 220 with screws. (See JP-A-7-272782, for example).

However, in this case too, the screws 216 are in a state exposed to a back face side of the mechanical chassis 220, as shown in FIG. 6B.

A second example of the prior art is shown in FIGS. 7, 8 and 9. In this example, a holder 301 is provided with screw insertion holes 306, and locking pieces 308 in a substantially L-shape respectively having base parts 309 extending from a lower face of the holder at positions near these screw insertion holes 306, and bosses 310 which are bent to extend from distal ends of the base parts 309. The bosses 310 are respectively provided with threaded holes 313 in a direction of their thickness. On the other hand, a chassis 302 is provided with locking holes 324 into which the locking pieces 308 are adapted to be inserted, and through holes 325 which are formed close to the locking holes 324 and adapted to communicate with the screw insertion holes 306. After the locking pieces 308 have been inserted into the locking holes 324, the holder 301 is made to slide so that the screw insertion holes 306, the through holes 325 and the threaded holes 313 may be communicated with one another, while apart of the chassis 302 is retained between the bosses 310 and the lower face of the holder 301. Then, the screws 331 are successively inserted into these holes, or at least into the threaded holes 313, and thus, the holder 1 can be mounted on the chassis 302. (See JP-A-2003-51685, for example).

However, also in this case, the screws 331 are exposed from the bosses 310.

### SUMMARY OF THE INVENTION

The invention has been made to solve the above described problem of the prior art, and it is an object of the invention to provide a mounting structure of a resin part on a chassis in which on occasion of mounting a leg portion of the resin part on a mounting part of the chassis by means of a screw, a tip end portion of this screw can be hidden, and thus, a screw of a particular type need not be employed.

The invention of aspect 1 is a mounting structure of a resin part on a chassis including a leg portion of the resin part, and a mounting part provided in the chassis which is adapted to mount the resin part thereon by tightening the leg portion with a screw. Preferably, the mounting part includes an upper piece in a horizontal direction which is cut and erected upwardly at a position for mounting the leg portion and both side pieces of which are integral with the chassis and inclined downwardly in an outward direction, the leg portion includes a blind hole which is dented about halfway of a thickness of the leg portion, the upper piece includes a screw hole vertically passing through at a position corresponding to the blind hole, the resin part is mounted on the chassis by inserting the leg portion horizontally into an opening below the upper piece and by screwing the screw into the screw hole, and a lower end of the screw comes into contact with a bottom of the blind hole and does not protrude to a back face side of the chassis.

Because the lower end of the screw comes into contact with the bottom of the blind hole of the resin part, and will not protrude to the back face side of the chassis, the tip end portion of the screw can be hidden when the leg portion of the resin part is mounted on the mounting part of the chassis by means of the screw, and there will be no need of employing a particular screw.

Moreover, because the leg portion of the resin part is inserted into the opening of the erected mounting part of the chassis, positioning of the resin part can be easily attained.

The invention of aspect 2 is a mounting structure of a resin part on a chassis including a leg portion of the resin part, and a mounting part provided in the chassis which is adapted to mount the resin part thereon by tightening the leg portion with a screw. Preferably, the mounting part includes an erected mounting part which is cut and erected upwardly at a position for mounting the leg portion and both side regions of which are formed integrally with the chassis to form right and left openings inside them, the leg portion includes a blind hole which is dented about halfway of a thickness of the leg portion, the erected mounting part includes a screw hole vertically passing through at a position corresponding to the blind hole in an upper region, the resin part is mounted on the chassis by inserting the leg portion horizontally into the openings and by screwing the screw into the screw hole, and a lower end of the screw comes into contact with a bottom of the blind hole and does not protrude to a back face side of the chassis.

Because the lower end of the screw comes into contact with the bottom of the blind hole of the resin part, and will not protrude to the back face side of the chassis, the tip end portion of the screw can be hidden when the leg portion of the resin part is mounted on the mounting part of the chassis by means of the screw, and there will be no need of employing a particular screw.

The invention of aspect 3 is the mounting structure of a resin part on a chassis of aspect 2, the mounting part has an upper piece in a horizontal direction which is cut and erected upwardly at a position for mounting the leg portion and both side pieces of which are integrally formed with the chassis in a vertical direction with respect to the upper piece.

The invention of aspect 4 is the mounting structure of a resin part on a chassis of aspect 2, the mounting part of the chassis has an upper piece in a horizontal direction which is cut and erected upwardly at a position for mounting the resin part and both side pieces of which are integral with the chassis and inclined downwardly in an outward direction, and a part to be inserted of the leg portion is formed in a trapezoidal shape in a sectional view to match with the right and left openings.

The invention of aspect 5 is a mounting method of a resin part on a chassis for mounting the resin part by tightening a leg portion of the resin part with a screw on a mounting part provided in the chassis including forming in the mounting part an upper piece in a horizontal direction which is cut and erected upwardly at a position for mounting the leg portion and both side pieces which are integral with the chassis and inclined downwardly in an outward direction, forming in the leg portion a blind hole which is dented about halfway of a thickness of the leg portion, forming in the upper piece a screw hole vertically passing through at a position corresponding to the blind hole, and mounting the resin part on the chassis by inserting the leg portion horizontally into an opening below the upper piece and screwing the screw into the screw hole. Preferably, a lower end of the screw comes into contact with a bottom of the blind hole and does not protrude to a back face side of the chassis.

### BRIEF DESCRIPTION OF THE DRAWINGS

Preferred embodiments of the present invention will be described in detail based on the following figures, wherein:

FIGS. 1A and 1B show a mounting structure of a resin part on a chassis in a first embodiment according to the invention, of which FIG. 1A is an exploded perspective view of the same, before mounting is conducted, and FIG. 1B is a sectional view of an essential part of the same, after the mounting has been conducted;

FIG. 2 is an exploded perspective view of the mounting structure of the resin part on the chassis in a second embodiment, before mounting is conducted;

FIG. 3 is an exploded perspective view of the mounting structure of the resin part on the chassis in a third embodiment, before mounting is conducted;

FIGS. 4A and 4B show a conventional mounting structure of a resin part on a chassis, of which FIG. 4A is an exploded perspective view of the same, before mounting is conducted, and FIG. 4B is a view of the same partly shown in section, after the mounting has been conducted;

FIG. 5 is an exploded perspective view of a conventional mounting mechanism of an electric part;

FIG. 6A is a plan view of the mounting mechanism in FIG. 5, and FIG. 6B is a side view of the mounting mechanism partly shown in section;

FIG. 7 is an exploded perspective view of a holder and a chassis in another conventional example;

FIG. 8 is a sectional view of the holder and the chassis in FIG. 7 in a state before mounting is conducted; and

FIG. 9 is a sectional view of the holder and the chassis in FIG. 7 in a state after the mounting has been conducted.

### DETAILED DESCRIPTION OF THE INVENTION

Now, an embodiment of a mounting structure of a resin part on a chassis according to the invention will be described referring to the drawings.

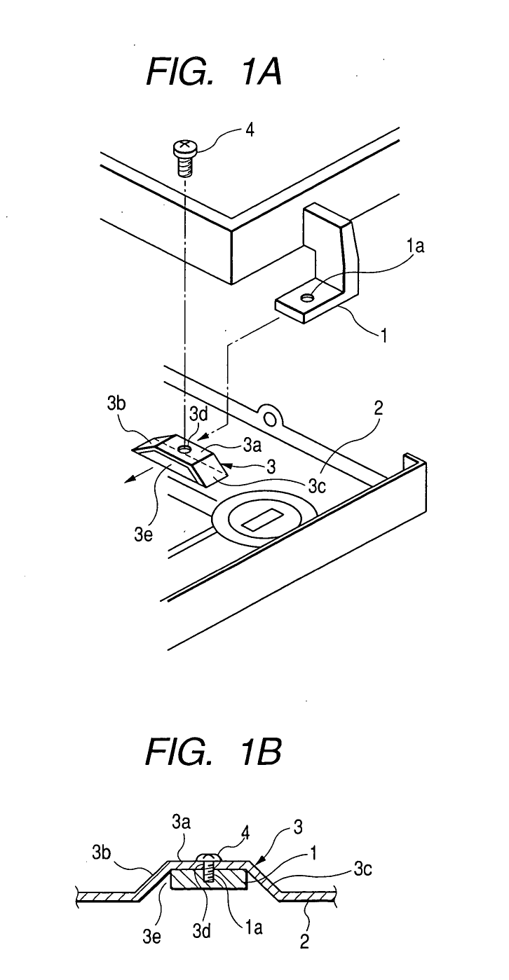

As shown in FIG. 1A, the mounting structure of the resin part on the chassis in this first embodiment is so constructed as to mount an L-shaped leg portion 1 of the resin part on a mounting part 3 which is provided at a determined position of a chassis 2, by tightening the leg portion 1 with a screw 4. The mounting part 3 of the chassis 2 has an upper piece 3a in a horizontal direction which is cut and erected upwardly at a position for mounting the resin part, and both side pieces 3b, 3c which are integral with the chassis 2 and inclined downwardly in an outward direction. In addition, the leg portion 1 of the resin part is formed with a blind hole 1a which is dented about halfway of a thickness of the leg portion 1, and the upper piece 3a of the erected mounting part 3 of the chassis 2 is formed with a screw hole 3d vertically passing through at a position corresponding to the blind hole 1a in the leg portion 1 of the resin part.

Then, the leg portion 1 of the resin part is horizontally inserted into an opening 3e below the upper piece 3a of the erected mounting part 3 of the chassis 2, and the screw 4 is screwed into the screw hole 3d in the upper piece 3a of the erected mounting part 3 of the chassis 2, until a lower end of the screw 4 comes into contact with a bottom of the blind hole 1a in the leg portion 1 of the resin part, thereby to mount the resin part on the chassis 2. In this manner, the lower end of the screw 4 will not protrude to a back face side of the chassis 2.

As the results, according to this first embodiment, because the lower end of the screw 4 comes into contact with the bottom of the blind hole 1a of the resin part, and will not protrude to the back face side of the chassis 2, the tip end portion of the screw 4 can be hidden when the leg portion 1 of the resin part is mounted on the mounting part 3 of the chassis 2 by means of the screw 4, and there will be no need of employing the screw 4 of a particular type.

Moreover, because the leg portion 1 of the resin part is inserted into the opening 3e of the erected mounting part 3 of the chassis 2, positioning of the resin part can be easily attained.

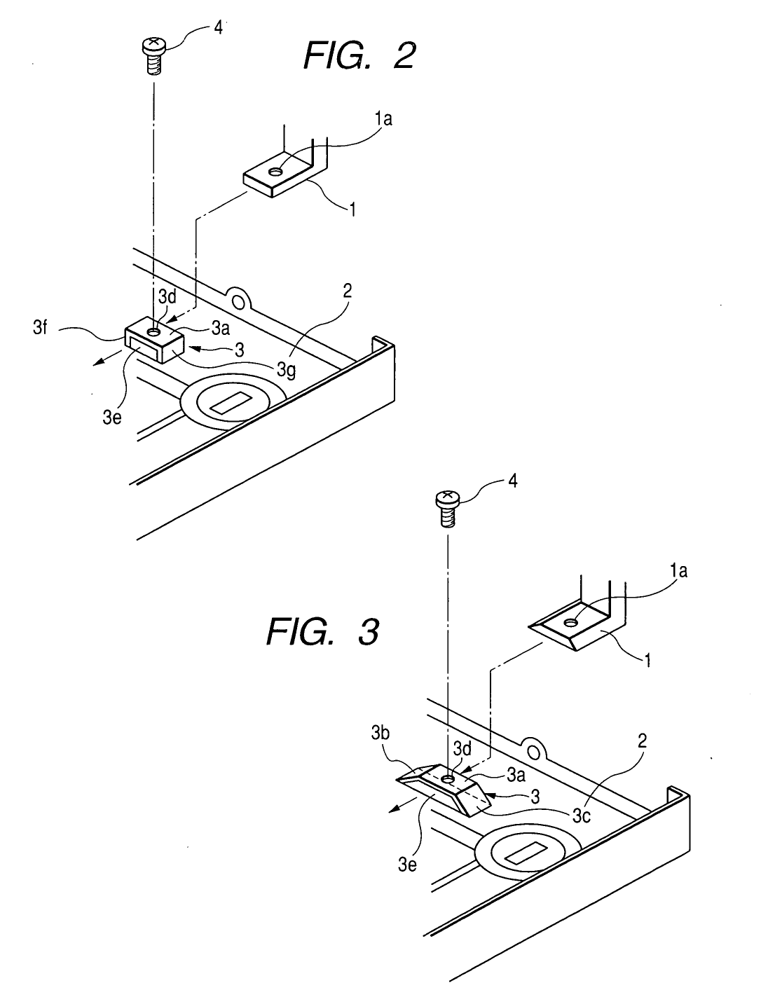

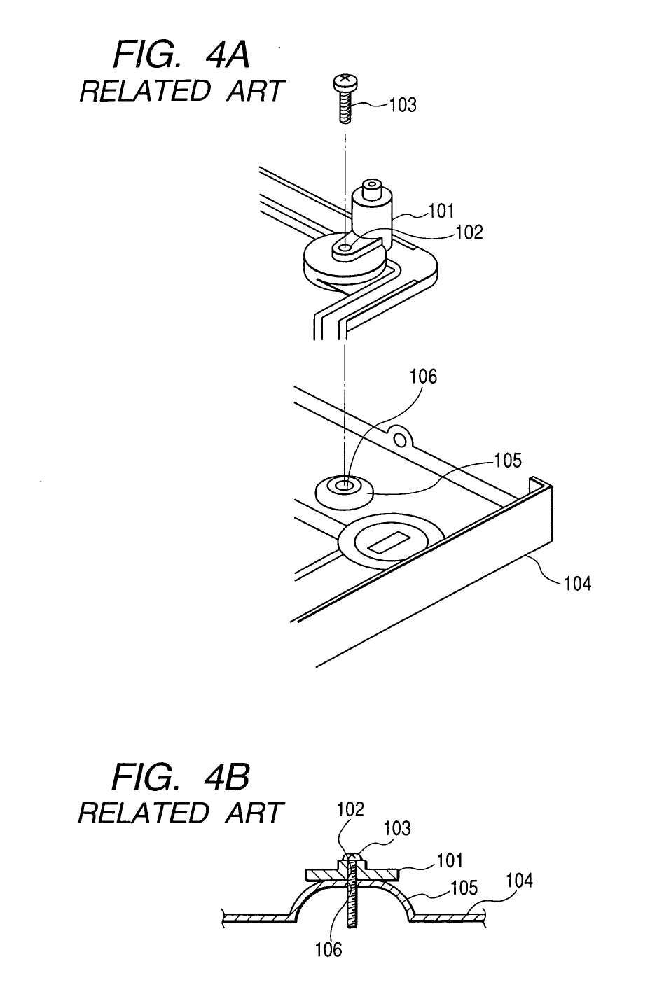

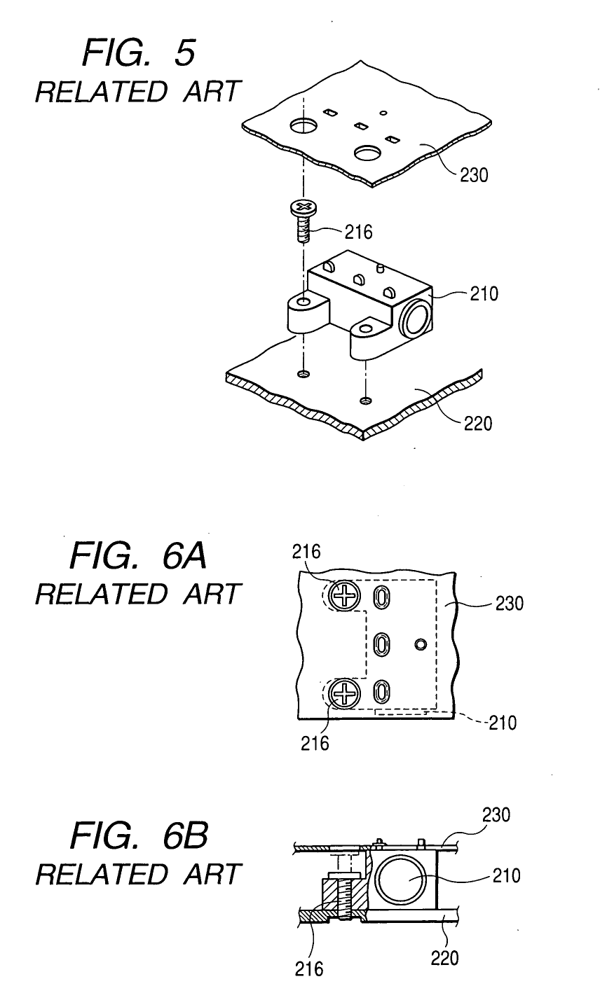

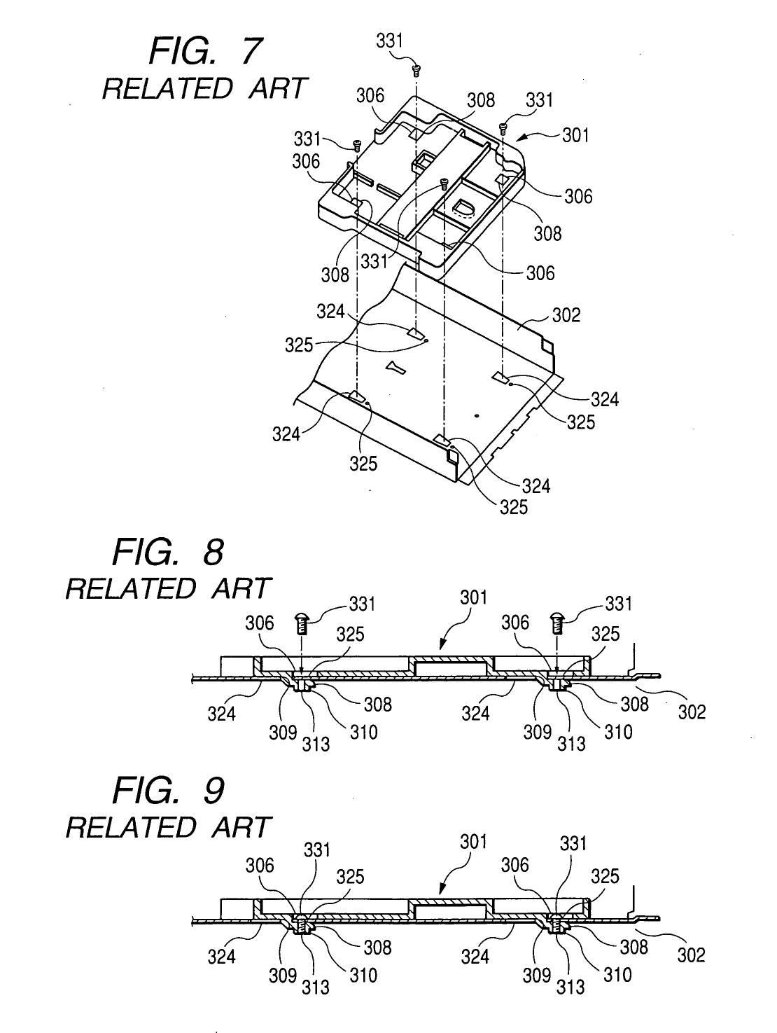

FIG. 2 is an exploded perspective view of the mounting structure of the resin part on the chassis according to a second embodiment, before mounting is conducted.

In the mounting structure of the resin part on the chassis in this second embodiment, as shown in FIG. 2, the mounting part 3 of the chassis 2 has the upper piece 3a in a horizontal direction which is cut and erected upwardly at a position for mounting the leg portion 1 of the resin part, and both side pieces 3f, 3g which are integrally formed with the chassis 2 in a vertical direction with respect to the upper piece 3a.

As the results, according to this second embodiment, the leg portion 1 of the resin part can be maintained in a stably mounted state, because the leg portion 1 is inserted into the opening 3e of the mounting part 3 of the chassis 2 without a gap.

FIG. 3 is an exploded perspective view of the mounting structure of the resin part on the chassis according to a third embodiment, before mounting is conducted.

In the mounting structure of the resin part on the chassis in this third embodiment, as shown in FIG. 3, the mounting part 3 of the chassis 2 has the upper piece 3a in a horizontal direction which is cut and erected upwardly at a position for mounting the leg portion 1 of the resin part, and both the side pieces 3b, 3c which are integral with the chassis 2 and inclined downwardly in an outward direction. On the other hand, a part to be inserted of the leg portion 1 of the resin part is formed in a trapezoidal shape in a sectional view so as to match with right and left openings 3e of the erected mounting part 3.

As the results, according to this third embodiment, because the leg portion 1 of the resin part in a trapezoidal shape can be inserted into the openings 3e of the erected mounting part 3 of the chassis 2 without a gap, this leg portion 1 will not be rubbed, but can be maintained in a stably mounted state.

1. Amounting structure of a resin part on a chassis comprising:
a leg portion of the resin part; and
a mounting part provided in the chassis which is adapted to mount the resin part thereon by tightening the leg portion with a screw,
wherein
the mounting part includes an upper piece in a horizontal direction which is cut and erected upwardly at a position for mounting the leg portion, and both side pieces of which are integral with the chassis and inclined downwardly in an outward direction,
the leg portion includes a blind hole which is dented about halfway of a thickness of the leg portion,
the upper piece includes a screw hole vertically passing through at a position corresponding to the blind hole,
the resin part is mounted on the chassis by inserting the leg portion horizontally into an opening below the upper piece, and by screwing the screw into the screw hole, and
a lower end of the screw comes into contact with a bottom of the blind hole, and does not protrude to a back face side of the chassis.

2. Amounting structure of a resin part on a chassis comprising:
a leg portion of the resin part; and
a mounting part provided in the chassis which is adapted to mount the resin part thereon by tightening the leg portion with a screw,
wherein
the mounting part includes an erected mounting part which is cut and erected upwardly at a position for mounting the leg portion, and both side regions of which are formed integrally with the chassis to form right and left openings inside them,
the leg portion includes a blind hole which is dented about halfway of a thickness of the leg portion,
the erected mounting part includes a screw hole vertically passing through at a position corresponding to the blind hole in an upper region,
the resin part is mounted on the chassis by inserting the leg portion horizontally into the openings, and by screwing the screw into the screw hole, and
a lower end of the screw comes into contact with a bottom of the blind hole, and does not protrude to a back face side of the chassis.

3. The mounting structure of a resin part on a chassis as claimed in claim 2,
wherein the mounting part has an upper piece in a horizontal direction which is cut and erected upwardly at a position for mounting the leg portion, and both side pieces of which are integrally formed with the chassis in a vertical direction with respect to the upper piece.

4. The mounting structure of a resin part on a chassis as claimed in claim 2,
wherein
the mounting part of the chassis has an upper piece in a horizontal direction which is cut and erected upwardly at a position for mounting the resin part, and both side pieces of which are integral with the chassis and inclined downwardly in an outward direction, and
a part to be inserted of the leg portion is formed in a trapezoidal shape in a sectional view to match with the right and left openings.

5. A mounting method of a resin part on a chassis for mounting the resin part by tightening a leg portion of the resin part with a screw on a mounting part provided in the chassis comprising:
forming in the mounting part an upper piece in a horizontal direction which is cut and erected upwardly at a position for mounting the leg portion, and both side pieces which are integral with the chassis and inclined downwardly in an outward direction,
forming in the leg portion a blind hole which is dented about halfway of a thickness of the leg portion,
forming in the upper piece a screw hole vertically passing through at a position corresponding to the blind hole, and
mounting the resin part on the chassis by inserting the leg portion horizontally into an opening below the upper piece, and screwing the screw into the screw hole,
wherein a lower end of the screw comes into contact with a bottom of the blind hole, and does not protrude to a back face side of the chassis.
